(19) United States
(12) Patent Application Publication
(10) Pub. No.: US 2009/0213641 A1
(43) Pub. Date: Aug. 27, 2009

(54) MEMORY WITH ACTIVE MODE BACK-BIAS VOLTAGE CONTROL AND METHOD OF OPERATING SAME

(76) Inventors: Heechoul Park, San Jose, CA (US); Song Chin Kim, San Jose, CA (US); Lancelot Y. Kwong, Fremont, CA (US); Wilson Fai Chin, Cupertino, CA (US)

Correspondence Address: BROOKS KUSHMAN P.C. / SUN / STK, 1000 TOWN CENTER, TWENTY-SECOND FLOOR, SOUTHFIELD, MI, 48075-1238, US

(21) Appl. No.: 12/035,601

(22) Filed: Feb. 22, 2008

(51) Int. Cl. G11C 11/00; G11C 7/00; G11C 8/00; G11C 5/14

(52) U.S. Cl. 365/154; 365/189.09; 365/226; 365/230.01

(57) ABSTRACT

Data storage cells of a static random access memory array are selectively provided with back-bias voltages to reduce current leakage during an active mode of operation. Circuitry electrically connected with the array receives control signals and provides the back-bias voltages to certain idle data storage cells of the array based on the control signals.

### BACKGROUND

1. Field of the Invention

The invention relates to memories with active mode back-bias voltage control and methods of operating the same.

2. Discussion

Electronic circuits are used in a variety of devices such as computers and cell phones. Certain of these electronic circuits include storage devices or memories. One type of memory is static random access memory (“SRAM”). SRAM uses bistable latching circuitry to store each bit. Unlike dynamic random access memory (DRAM), SRAM does not need to be periodically refreshed. SRAM, however, is still volatile in that data is lost when powered down.

SRAM arrays are operable in active and standby modes. The active mode comprises a period of time during which data cells of the array may be accessed, i.e., read from or written to. The standby mode comprises a period of time during which data cells of the array are not accessed and during which a data state stored in each of the data cells is to be maintained at a valid state.

Several techniques are known for adjusting voltages to SRAM arrays during the standby mode. U.S. Pat. No. 7,307,907 to Houston provides an example of one such technique. Houston discloses an SRAM device that includes an SRAM array coupled to row peripheral circuitry by a word line and coupled to column peripheral circuitry by bit lines. The SRAM device also includes a standby mode voltage controller configured to provide both an array high supply voltage that is lower than a high operating voltage and an array low supply voltage that is higher than a low operating voltage to the SRAM array during the standby mode.

U.S. Pat. No. 6,982,915 to Houston et al. provides another example of such a technique. Houston et al. discloses an electronic device comprising a plurality of data storage cells collectively operable in the active mode and separately in the standby mode. The electronic device further comprises circuitry for providing at least one temperature-dependent voltage to at least one storage device in each cell in the plurality of data storage cells during the standby mode.

The paper entitled “Design of a Process Variation Tolerant Self-Repairing SRAM for Yield Enhancement in Nanoscaled CMOS,” Mukhopadhyay et al., IEEE Journal of Solid-State Circuits, Vol. 42, No. 6, June 2007, pp. 1370-1382, provides yet another example of such a technique. Mukhopadhyay et al. proposes a self-repairing SRAM to reduce parametric failures. Depending on an inter-die threshold shift, the self-repairing system selects a proper body bias for the SRAM. A current sensor circuit monitors the leakage of the entire SRAM array and generates an output voltage that is proportional to the leakage value. The output of the leakage monitor is compared with reference voltages corresponding to different inter-die process corners. Based on the results of this comparison, a body bias selection circuit applies the proper body bias to the SRAM array. A PMOS switch bypasses the leakage monitor during the active mode of operation.

### SUMMARY

An electronic memory device includes an array of memory storage cells collectively operable in an active mode and a standby mode. At least one of the memory storage cells is accessed during the active mode. The memory storage cells are idle during the standby mode. The device also includes circuitry to provide a back-bias voltage to at least one of the memory storage cells of the array during the active mode.

A static random access memory array includes a plurality of data cells and circuitry being configured to provide a back-bias voltage to one of the plurality of data cells while another of the plurality of data cells is being accessed.

A method for reducing leakage current in a static random access memory array includes providing a back-bias voltage to one of a plurality of memory storage cells while another one of the plurality of memory storage cells is being accessed thereby reducing leakage current in the one memory storage cell.

While exemplary embodiments in accordance with the invention are illustrated and disclosed, such disclosure should not be construed to limit the claims. It is anticipated that various modifications and alternative designs may be made without departing from the scope of the invention.

### BRIEF DESCRIPTION OF THE DRAWINGS

FIG. 1 is a schematic diagram of a CMOS memory storage cell in accordance with an embodiment of the invention.

FIG. 2 is a schematic diagram of an array of CMOS memory storage cells and associated back-bias control circuits in accordance with an embodiment of the invention.

FIG. 3 is a schematic diagram of one of the back-bias control circuits of FIG. 2.

FIG. 4 is a schematic diagram of a CMOS memory storage cell in accordance with another embodiment of the invention.

FIG. 5 is a schematic diagram of an array of CMOS memory storage cells and associated back-bias control circuits in accordance with another embodiment of the invention.

FIG. 6 is a schematic diagram of one of the back-bias control circuits of FIG. 5.

### DETAILED DESCRIPTION

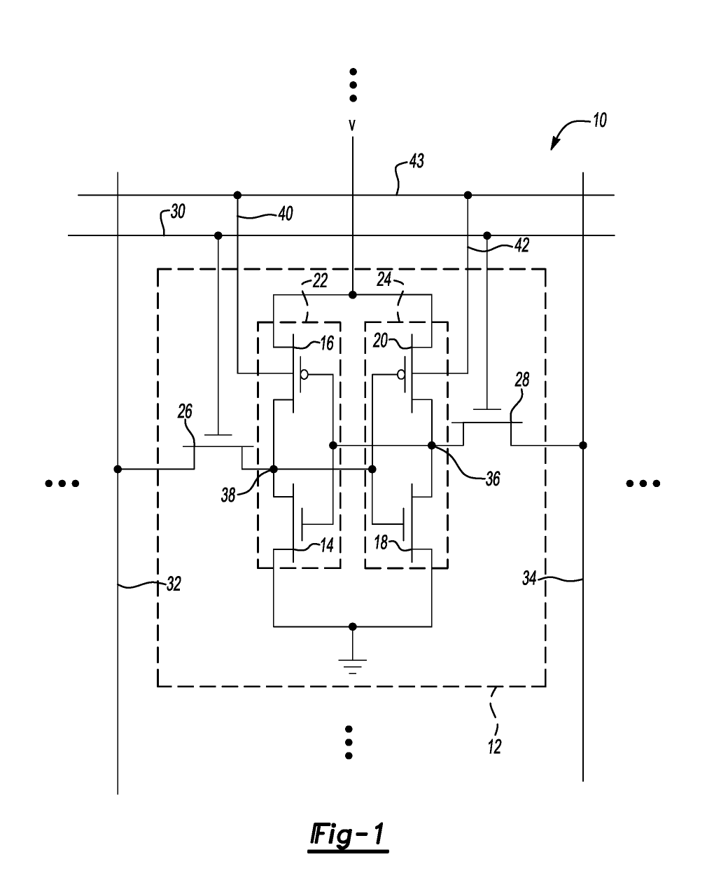

Referring now to FIG. 1, a bit of a CMOS SRAM array 10 is stored in one of a plurality of storage cells 12. In the embodiment of FIG. 1, the storage cell 12 includes field effect transistors 14, 16, 18, 20. The transistors 14, 16, 18, 20 form cross-coupled inverters 22, 24. The storage cell 12 thus has two stable states which are used to denote 0 and 1. The storage cell 12 also includes access field effect transistors 26, 28. The access transistors 26, 28 control access to the storage cell 12 during read and write operations.

A typical storage cell of an SRAM, such as the embodiment of the storage cell 12 of FIG. 1, uses six MOSFETs (6T) to store each memory bit. Other SRAM chips may use 8T, 10T or more transistors per bit to, for example, implement more ports in a register file. Generally, the size of a storage cell is determined by the number of transistors. Smaller storage cells reduce the cost per bit of memory because the cost of processing a silicon wafer is relatively fixed.

A word line 30 enables access to the storage cell 12 by controlling the access transistors 26, 28. The access transistors 26, 28 control whether the storage cell 12 is connected to bit lines 32, 34 respectively. The bit lines 32, 34 are used to transfer data for both read and write operations. Fewer bit lines may be used. Both the signal and its inverse, however, are typically provided to improve noise margins.

The bit lines 32, 34 are actively driven high and low by the cross-coupled inverters 22, 24. This improves speed compared to DRAMs. In a typical DRAM, the bit line is connected to storage capacitors. Charge sharing causes the bit line to swing upwards or downwards.

The symmetric structure of SRAM storage cells, as in the embodiment of the storage cell 12 of FIG. 1, allows for differential signaling. Differential signaling facilitates the detection of small voltage swings.

The SRAM 10 has two different modes: standby and active. During standby mode, the storage cell 12 is idle. The access transistors 26, 28 disconnect from the bit lines 32, 34 respectively if the word line 30 is not asserted. The cross-coupled inverters 22, 24 reinforce each other as long as the access transistors 26, 28 are disconnected from the bit lines 32, 34 respectively.

A voltage, v, provided to the SRAM 10 is typically reduced to a data retention voltage during standby mode as compared to a voltage provided during active mode. For example, if the voltage, v, provided to the SRAM 10 is V_{dd} during active mode, the voltage, v, provided during standby mode is 0.5V_{dd}. The specific amount of reduction, however, is generally dictated by design considerations. For example, with an anticipated range of environmental and circuit conditions such as temperature, silicon variations, and the like, the reduced value of the voltage is fixed at a level to ensure that the data state is maintained in each storage cell 12 during standby mode.

During active mode, the storage cell 12 may be read, written or idle. For a read operation, assuming that the storage cell 12 is storing a 1, a node 36 will be high at V_{dd} and a node 38 will be low. Before reading begins, the bit lines 32, 34 are precharged to a voltage between the low and high values. When the word line 30 is asserted and transistors 26, 28 are turned on, current will flow from V_{dd} through transistors 20, 28 and onto bit line 34. Current will also flow from the bit line 32 through transistors 26, 14 to ground.

For a write operation, assuming that the storage cell 12 is storing a 1 and a 0 is to be written, the node 36 will be high at V_{dd} and the node 38 will be low. The bit line 34 is lowered to 0V and the bit line 32 is raised to V_{dd}. The storage cell 12 is selected by raising the word line 30 to V_{dd}. The value to be stored is then latched.

When the storage cell 12 is idle, leakage currents may flow through the transistors 14, 16, 18, 20, 26, 28 because of their relatively small size. As explained below, back-bias lines 40, 42 may apply a back-bias voltage, V_{bb}, to the transistors 16, 20 respectively to reduce and/or eliminate these leakage currents during the active mode. The resulting total voltage applied to each of the transistors 16, 20 is thus equal to V_{dd}+V_{bb}. The back-bias voltages reduce and/or eliminate these leakage currents by altering the threshold voltages associated with the transistors 16, 20. The back-bias lines 40, 42 are electrically connected with a feed line 43. As explained below, the feed line 43 selectively provides the back-bias voltage.

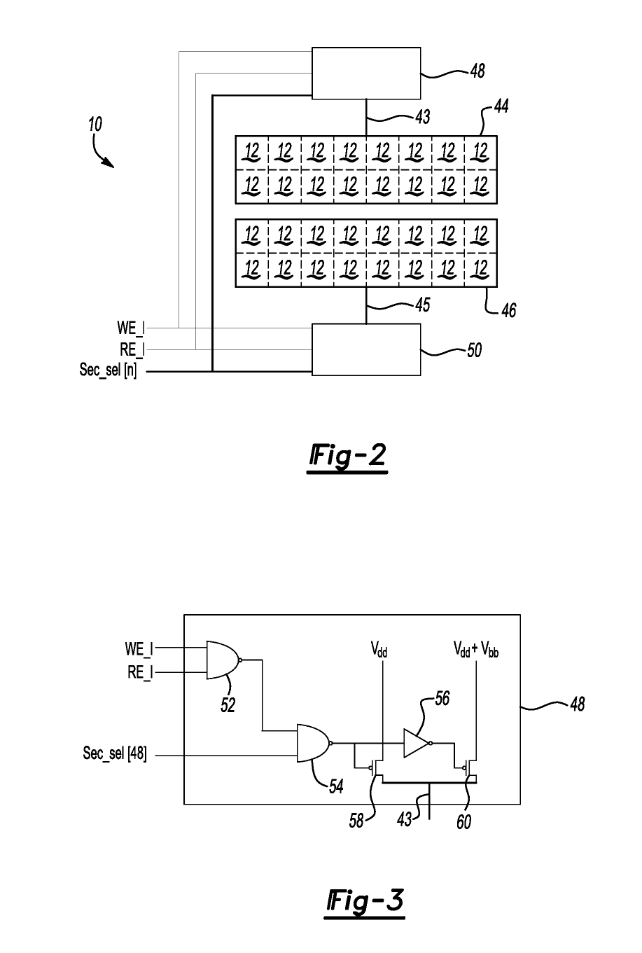

Referring now to FIG. 2, the storage cells 12 of the SRAM 10 are arranged in sections 44, 46 each including (16) storage cells 12. In other embodiments, the storage cells 12 of the SRAM array 10 may be arranged in any number of sections each including any number of storage cells. For example, (100,000) storage cells 12 maybe arranged in (10) sections each including (10,0000) storage cells 12.

Back-bias control circuits 48, 50 are electrically connected, via the feed lines 43, 45, with the storage cells 12 of the sections 44, 46 respectively. The back-bias control circuits 48, 50 selectively apply a back-bias voltage to the storage cells 12 of the sections 44, 46 respectively. For example, if the SRAM array 10 is in active mode, the storage cells 12 of the section 44 may be read and the storage cells 12 of the section 46 may be idle. To facilitate such reading, the back-bias control circuit 48 does not apply a back-bias voltage to the storage cells 12 associated with the section 44. To reduce and/or eliminate leakage currents, the back-bias control circuit 46 applies a back-bias voltage to the storage cells 12 associated with the section 46.

Referring now to FIG. 3, an embodiment of the back-bias control circuit 48 includes logic gates 52, 54, an inverter 56, and transistors 58, 60. The logic gates 52, 54 are cascaded NAND gates. The output of the NAND gate 54 is electrically connected with the transistor 58 and the input of the inverter 56. As explained below, control signals, e.g., WE_1, RE_1 and Sec_se1[n], generated in typical fashion from memory address signals enable the back-bias control circuit 48 to selectively apply a back-bias voltage to the feed line 43. In other embodiments, any suitable combination of logic gates, e.g., AND, OR, NOR, etc., operatively arranged to decode the control signals and activate suitable switches, e.g., FETs, etc., to allow the back-bias control circuit 48 to selectively apply a back-bias voltage to the feed line 43 may be used.

As apparent to one of ordinary skill, if Sec_se1[n] is high, then the section associated with Sec_se1[n] is to be read from or written to during active mode. For example, if Sec_se1[44] is high, then section 44 will be read from or written to during active mode. If Sec_se1[44] is low, then section 44 will be idle during active mode. Similarly, if Sec_se1[46] is high, then section 46 will be read from or written to during active mode. If Sec_se1[46] is low, then section 46 will be idle during active mode.

WE_1 and RE_1 are high in the absence of a write or read. If WE_1 is low, a write is requested. If RE_1 is low, a read is requested.

As mentioned above, the back-bias control circuits 48, 50 selectively apply a back-bias voltage to the storage cells 12 of the sections 44, 46 respectively. For example, if the SRAM array 10 is in active mode, the storage cells 12 of the section 44 may be read and the storage cells 12 of the section 46 may be idle. In this case, Sec_se1[44] is high, Sec_se1[46] is low, WE_1 is high and RE_1 is low. The output of the NAND gate 52 will be high. The output of the NAND gate 54 will be low. This low output will enable the transistor 58 to electrically connect the feed line 43 with V_{dd} thereby not providing a back-bias voltage to the storage cells 12 associated with the section 44. This low output will also be inverted to a high by the inverter 56. This high will prevent the transistor 60 from electrically connecting the feed line 43 with V_{dd}+V_{bb}.

If the SRAM array 10 is in active mode, the storage cells 12 of the section 44 may be idle and the storage cells 12 of the section 46 may be written. In this case, Sec_se1[44] is low, Sec_[46] is high, WE_1 is low and RE_1 is high. The output of the NAND gate 52 will be high. The output of the NAND gate 54 will also be high. This high output will prevent the transistor 58 from electrically connecting the feed line 43 with V_{dd}. This high output will also be inverted to a low by the inverter 56. This low will enable the transistor 60 to electrically connect the feed line 43 with V_{dd}+V_{bb} thereby providing a back-bias voltage to the storage cells 12 associated with the section 44.

The configuration and operation of the back-bias control circuit 50 is similar to that of the back-bias control circuit 48.

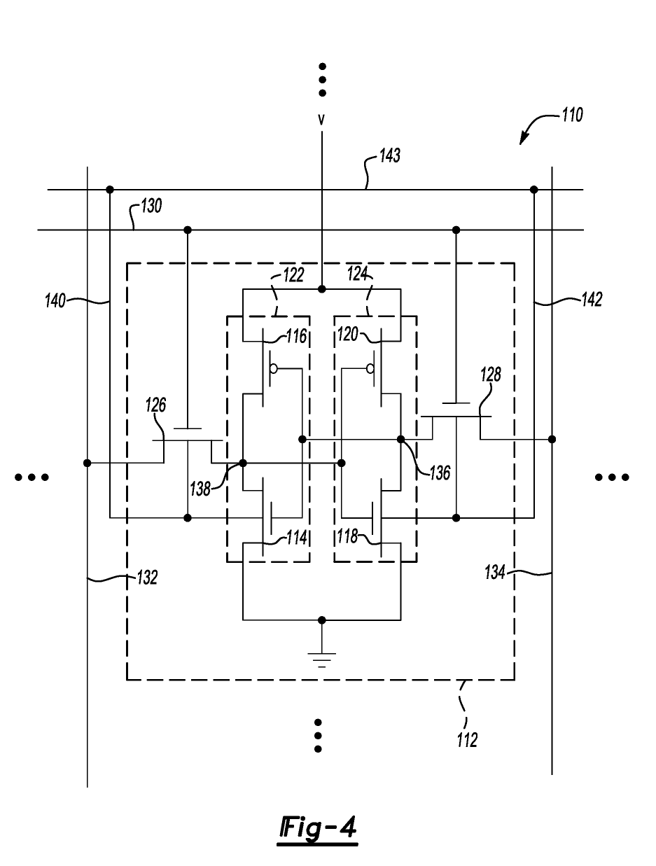

Referring now to FIG. 4, a bit of a CMOS SRAM array 110 is stored in one of a plurality of storage cells 1 12. Numbered elements of FIG. 4 that differ by 100 relative to numbered elements of FIG. 1 have similar, although not necessarily identical, descriptions to the numbered elements of FIG. 1. For example, the description of the operation of the storage cell 12 of FIG. 1 generally applies to the storage cell 112 of FIG. 4.

When the storage cell 112 is idle, leakage currents may flow through the transistors 114, 116, 118, 120, 126, 128 because of their relatively small size. As explained below, back-bias lines 140, 142 may apply a back-bias voltage, V_{bb}, to the transistors 114, 126 and 118, 128 respectively to reduce and/or eliminate these leakage currents during the active mode. The resulting total voltage applied to each of the transistors 114, 126, 118, 128 is thus equal to Vₛₛ−V_{bb} where Vₛₛ, in the embodiment of FIG. 4, is equal to ground. Other voltages, however, may be used. The back-bias voltages reduce and/or eliminate these leakage currents by altering the threshold voltages associated with the transistors 114, 126 and 118, 128. The back-bias lines 140, 142 are electrically connected with a feed line 143. As explained below, the feed line 143 selectively provides the back-bias voltage.

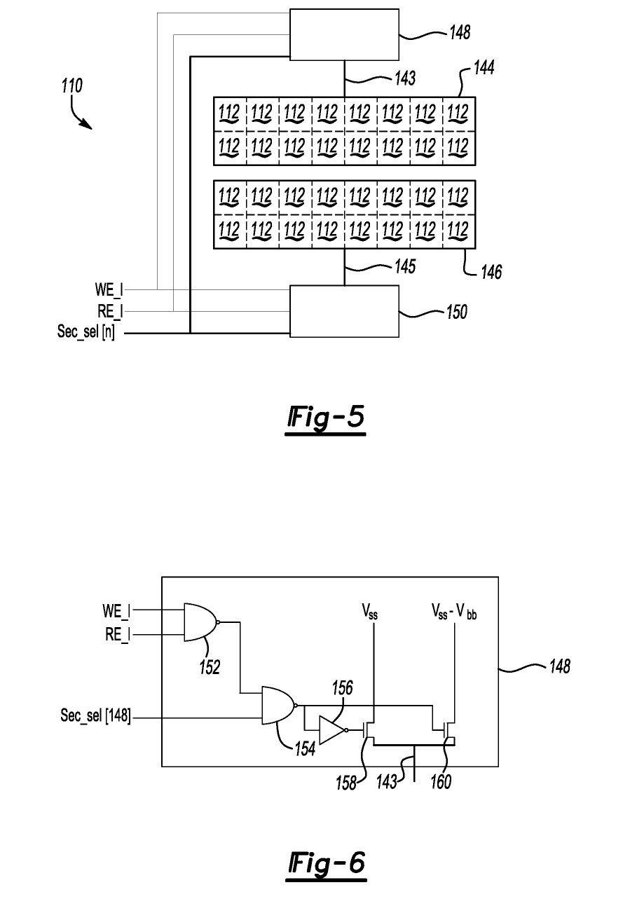

Referring now to FIG. 5, the storage cells 112 of the SRAM 110 are arranged in sections 144, 146 each including (16) storage cells 112. Numbered elements of FIG. 5 differing by 100 relative to numbered elements of FIG. 2 have similar, although not necessarily identical, descriptions to the numbered elements of FIG. 2.

Back-bias control circuits 148, 150 are electrically connected, via the feed lines 143, 145, with the storage cells 112 of the sections 144, 146 respectively. As explained below, the back-bias control circuits 148, 150 selectively apply a back-bias voltage to the storage cells 112 of the sections 144, 146 respectively.

Referring now to FIG. 6, the back-bias control circuit 148 includes logic gates 152, 154, an inverter 156, and transistors 158, 160. The logic gates 152, 154 are cascaded NAND gates. The output of the NAND gate 154 is electrically connected with the input of the inverter 156 and the transistor 160. As explained below, control signals, e.g., WE_1, RE_1 and Sec_se1[n], generated in typical fashion from memory address signals enable the back-bias control circuit 148 to selectively apply a back-bias voltage to the feed line 143.

As mentioned above, the back-bias control circuits 148, 150 selectively apply a back-bias voltage to the storage cells 112 of the sections 144, 146 respectively. For example, if the SRAM array 110 is in active mode, the storage cells 112 of the section 144 may be read and the storage cells 112 of the section 146 may be idle. In this case, Sec_se1[144] is high, Sec_se1[146] is low, WE_1 is high and RE_1 is low. The output of the NAND gate 152 will be high. The output of the NAND gate 154 will be low. The low output will inverted to a high by inverter 156. This high will enable the transistor 158 to electrically connect the feed line 143 with Vₛₛ thereby not providing a back-bias voltage to the storage cells 112 associated with the section 144. The low output will also prevent the transistor 160 from electrically connecting the feed line 143 with Vₛₛ−V_{bb}.

If the SRAM array 110 is in active mode, the storage cells 112 of the section 144 may be idle and the storage cells 112 of the section 146 may be written. In this case, Sec_se1[144] is low, Sec_[146] is high, WE_1 is low and RE_1 is high. The output of the NAND gate 152 will be high. The output of the NAND gate 154 will be high. The high output will be inverted to a low by the inverter 156. This low will prevent the transistor 158 from electrically connecting the feed line 143 with Vₛₛ. The high output will enable the transistor 160 to electrically connect the feed line 143 with Vₛₛ−V_{bb} thereby providing a back-bias voltage to the storage cells 112 associated with the section 144.

The configuration and operation of the back-bias control circuit 150 is similar to that of the back-bias control circuit 148.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. An electronic memory device comprising:
an array of memory storage cells collectively operable in an active mode and a standby mode, at least one of the memory storage cells being accessed during the active mode and the memory storage cells being idle during the standby mode; and
circuitry to provide a back-bias voltage to at least one of the memory storage cells of the array during the active mode.

2. The device of claim 1 wherein the array of memory storage cells comprises a static random access memory array.

3. The device of claim 1 wherein each memory storage cell of the array includes a plurality of transistors and wherein the circuitry is configured to provide the back-bias voltage to at least one of the plurality of transistors to alter a threshold voltage of the at least one of the plurality of transistors to reduce a leakage current associated with the at least one of the plurality of transistors.

4. The device of claim 1 wherein the circuitry includes (i) a first logic gate configured to receive operation control signals indicative of a read or write request for memory storage cells and to provide a first output based on the operation control signals, and (ii) a second logic gate configured to receive the first output and a section control signal indicative of a section of memory storage cells of the array to be accessed and to provide a second output based on the first output and the section control signal.

5. The device of claim 4 wherein the logic gates comprise NAND gates.

6. The device of claim 4 further comprising a first voltage source wherein the circuitry provides a back-bias voltage to at least one of the memory storage cells of the array during the active mode via a feed line and wherein the first voltage source is selectively electrically connected with the feed line based on the second output.

7. The device of claim 6 further comprising a second voltage source wherein the second voltage source is selectively electrically connected with the feed line based on a compliment of the second output.

8. A static random access memory array comprising:
a plurality of data cells; and
circuitry being configured to provide a back-bias voltage to one of the plurality of data cells while another of the plurality of data cells is being accessed.

9. The array of claim 8 wherein each of the plurality of data cells includes a plurality of transistors and wherein the circuitry is configured to provide the back-bias voltage to at least one of the plurality of transistors to alter a threshold voltage of the at least one of the plurality of transistors to reduce a leakage current associated with the at least one of the plurality of transistors.

10. The array of claim 8 wherein the circuitry includes (i) a first logic gate configured to receive operation control signals indicative of a read or write request for data cells and to provide a first output based on the operation control signals, and (ii) a second logic gate configured to receive the first output and a section control signal indicative of a section of data cells of the array to be accessed and to provide a second output based on the first output and the section control signal.

11. The array of claim 10 wherein the logic gates comprise NAND gates.

12. The array of claim 10 further comprising a first voltage source wherein the circuitry provides a back-bias voltage to the one of the plurality of data cells via a feed line and wherein the first voltage source is selectively electrically connected with the feed line based on the second output.

13. The array of claim 12 further comprising a second voltage source wherein the second voltage source is selectively electrically connected with the feed line based on a compliment of the second output.

14. The array of claim 13 wherein the first and second voltage sources are selectively electrically connected with the feed line via a pair of transistors.

15. A method for reducing leakage current in a static random access memory array including a plurality of memory storage cells, the method comprising:
providing a back-bias voltage to one of the plurality of memory storage cells while another one of the plurality of memory storage cells is being accessed thereby reducing leakage current in the one memory storage cell.

16. The method of claim 15 wherein providing a back-bias voltage to one of the plurality of memory storage cells includes altering a transistor threshold voltage associated with the one of the plurality of memory storage cells.

17. The method of claim 15 wherein accessing another one of the plurality of memory storage cells includes at least one of reading from and writing to the another one of the plurality of memory storage cells.
